(19) United States
(12) Patent Application Publication
(10) Pub. No.: US 2011/0077878 A1
(43) Pub. Date: Mar. 31, 2011

(54) POWER SUPPLY WITH DATA COMMUNICATIONS

(76) Inventors: Frederick L. Lathrop, Spring, TX (US); Jeffrey K. Jeansonne, Houston, TX (US); James L. Mondshine, Cypress, TX (US)

(21) Appl. No.: 12/570,154

(22) Filed: Sep. 30, 2009

(51) Int. Cl. G01R 21/00; G06F 19/00

(52) U.S. Cl. 702/62

(57) ABSTRACT

Apparatus and methods are provided for use with smart utility grids. A smart power supply includes power metering to determine instantaneous and cumulative energy consumption of the power supply and a computer coupled thereto. Communications transceivers enable the smart power supply to communicate with both the computer and smart entities of a smart utility grid. A user of the computer can view energy consumption data, utility rates, utility loading and other energy-related information by way of the smart power supply.

### BACKGROUND

Power supplies are widely used in providing operating electrical energy to computers, cellular telephones and other devices. Typically, alternating-current (AC) power is received from a utility source and converted to direct-current energy of regulated or limited voltage. Such conditioned electrical power can then be provided to a desktop computer, laptop computer or other load.

Smart utility grids utilize digital communications to exchange information such as power consumption, utility rates, present grid loading and other data between the utility operator and various smart devices. However, most computers in use today do not have the resources needed to leverage a smart utility grid in a meaningful way. As a result, power conservation and cost savings opportunities are not realized. The present teachings address the foregoing concerns.

### BRIEF DESCRIPTION OF THE DRAWINGS

The present embodiments will now be described, by way of example, with reference to the accompanying drawings, in which:

FIG. 1 depicts a block diagrammatic view of a system according to one embodiment;

FIG. 2 depicts a flow diagram of a method according to one embodiment;

FIG. 3 depicts a flow diagram of a method according to one embodiment;

FIG. 4A depicts a block diagrammatic view of a system according to another embodiment;

FIG. 4B depicts a perspective view of a portion of the system of FIG. 4A;

FIG. 5 is a block diagrammatic view of an apparatus according to one embodiment.

### DETAILED DESCRIPTION

### Introduction

Means and methods for use with smart utility grids are provided by the present teachings. A smart power supply includes power metering to determine instantaneous and cumulative energy consumption of the power supply and of a computer coupled thereto. Communications transceivers enable the smart power supply to communicate with both the computer and smart entities of a smart utility grid. A user of the computer can view energy consumption data, utility rates, utility loading and other energy-related information by way of the smart power supply.

In one embodiment, a power supply includes a controller. The controller includes a processor. The power supply also includes metering configured to measure electrical power provided from source to the power supply, and to provide corresponding power values to the controller. Additionally, the power supply includes a first transceiver that is configured to couple the controller in communication with a computer. The power supply further includes a second transceiver that is configured to couple the controller in communication with the source.

In another embodiment, a method includes measuring electrical power provided from a source to a power supply. The method also includes communicating data corresponding to the measuring from the power supply to a computer. The computer is electrically coupled to receive operating power from the power supply.

### First Illustrative System

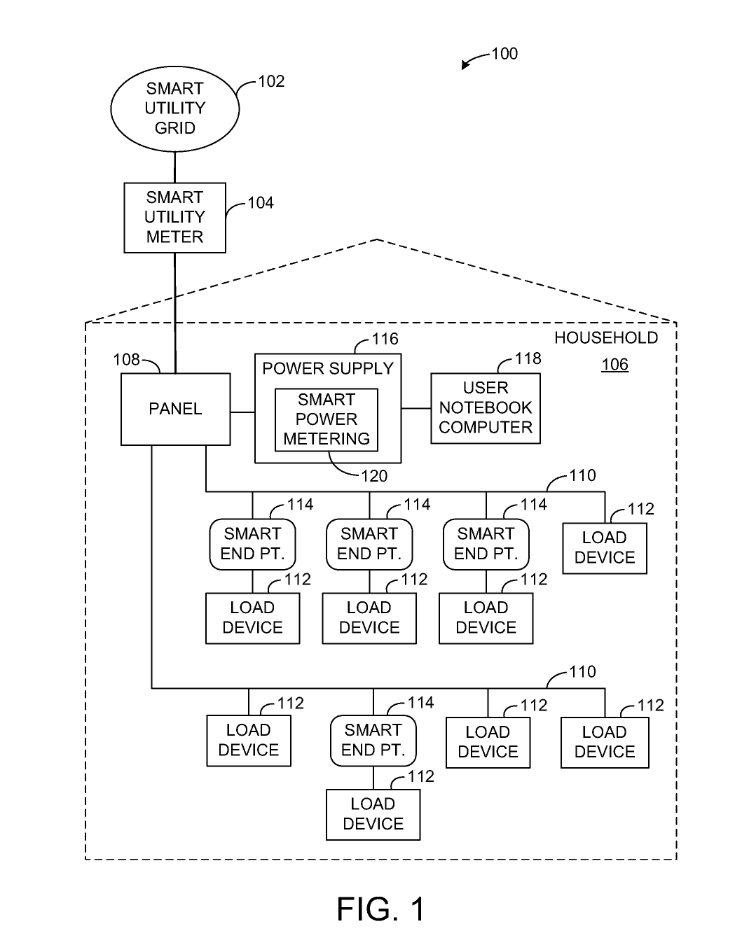

Reference is now directed to FIG. 1, which depicts a diagrammatic view of a system 100. The system 100 is illustrative and non-limiting with respect to the present teachings. Thus, other systems can be configured and/or operated in accordance with the present teachings.

The system 100 includes a smart utility grid 102. The smart utility grid 102 is characterized by the distribution of electrical power to numerous receiving clients. The smart utility grid 102 is further characterized by the bidirectional communication of data and information by way of digital signals superimposed onto the line-level electrical power (e.g., one-hundred twenty volts, etc.) provided by the grid 102.

Such data and information can include, without limitation: present or scheduled utility rates, present loading of the smart utility grid 102, instantaneous power consumption of a particular load, totalized power consumption of a particular load, present power factor of a load or a portion of the smart utility grid 102, etc. It is the exchange of such energy-related data and information, and the opportunity to schedule or throttle load operations accordingly, that distinguishes the smart utility grid 102 from other, classical forms of power distribution system.

The system 100 includes a smart utility meter 104. The smart utility meter 104 is configured to measure and totalize overall electrical power consumption within a household 106. The smart utility meter 104 is further configured to communicate with the smart utility grid 102 and various entities within the household 106 and to store information reported thereto. In this way, the smart utility meter 104 serves as a centralized metering and communications node coupling the household 106 to the smart utility grid 102.

The system 100 includes a panel 108. The panel 108 is defined by a conventional electrical distribution panel including numerous circuit breakers (not shown) that couple respective branch circuits 110 to line-level electrical energy provided by the smart utility grid 102. One having ordinary skill in the electrical arts is familiar with distribution panels such as panel 108, and further elaboration is not required for an understanding of the present teachings.

The system 100 further includes a number of load devices 112. The load devices 112 are defined by respective various entities that receive operating electrical energy from an associated branch circuit 110. Non-limiting examples of load devices 112 include television sets, kitchen appliances, laundry appliances, air conditioning equipment, electric heaters, lamps, etc. Other load devices 112 can also be defined and used. As such, each load device 112 consumes some respective (and possibly varying) quantity of electrical energy during normal operation.

The system 100 also includes a number of smart end points 114. Each smart end point 114 is configured to measure electrical energy consumed by an associated load device 112 and to communicate with other smart entities such as the smart utility meter 104. At least some of the smart end points 114 are further configured to provide some level of control of the associated load device 112. For non-limiting example, a particular smart end point 114 can provide time-of-day scheduling for operating the corresponding load device 112 during times of reduced utility rates (i.e., lower electrical costs). In another non-limiting example, a particular smart end point 114 is configured to throttle the operation of the load device 112 so as to reduce electrical consumption by a predetermined amount (e.g., percentage, etc.). Other control stratagems can also be used.

The smart utility grid 102, the smart utility meter 104 and the smart end points 114 described above can be of suitable known or future technology. One having skill in the electrical arts is familiar with smart grid technology, devices and the normal operations thereof, and further illustrative elaboration is provided hereinafter in order to clarify the present teachings.

The system 100 includes a power supply 116. The power supply 116 is configured to receive electrical energy from the smart utility grid 102 by way of the panel 108, and to provide conditioned electrical energy to a user notebook computer 118. The power supply 116 includes smart power metering 120 that is configured to measure electrical energy consumed by the power supply 116 and the computer 118, and to communicate those energy consumption values to the smart utility meter 104 and the computer 118. As such, the smart power metering 120 includes various resources in order to perform numerous normal operations as described in further detail below. The power supply 116 is also referred to as a smart power supply 116 for purposes of the present teachings.

### First Illustrative Method

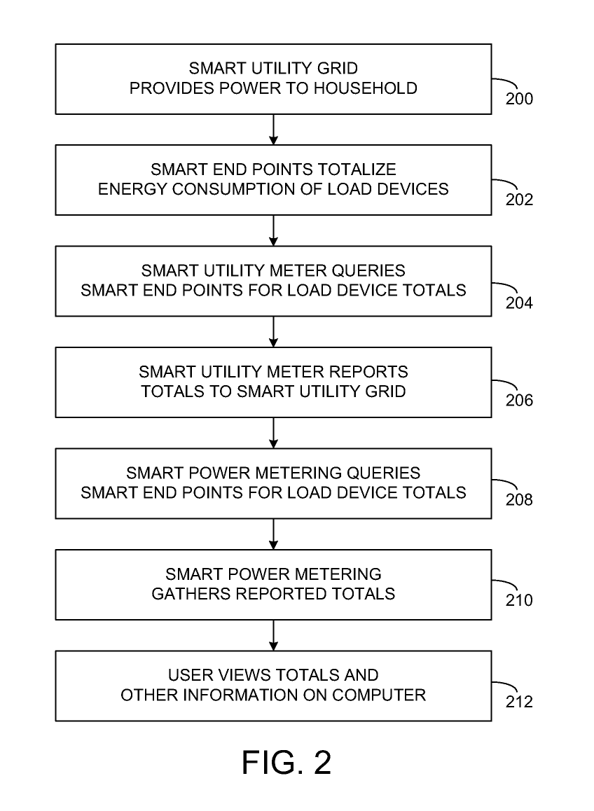

FIG. 2 is a flow diagram depicting a method according to one embodiment of the present teachings. The method of FIG. 2 includes particular operations and order of execution. However, other methods including other operations, omitting one or more of the depicted operations, and/or proceeding in other orders of execution can also be used according to the present teachings. Thus, the method of FIG. 2 is illustrative and non-limiting in nature. Reference is also made to FIG. 1 in the interest of understanding the method of FIG. 2.

At 200, a smart utility grid provides electrical power to a household. For purposes of non-limiting illustration, it is assumed that the smart utility grid 102 provide line-level electrical power to the household 106 by way of the smart utility meter 104 and the panel 108.

At 202, smart end points measure and totalize electrical power consumption of respective load devices. For purpose of the ongoing illustration, it is assumed that the smart end points 114 measure and totalize (i.e., time integrate) electrical power consumption of respective load devices 112. Such totalized information can be stored within the smart end points 114 in terms of Kilowatt hours, volt-ampere hours, etc.

At 204, a smart utility meter queries the smart end points for energy consumption totals for the load devices. For purpose of the ongoing illustration, it is assumed that the smart utility meter 104 queries the smart end points 114 for the most recent energy consumption totals that they have accumulated for the respective load devices 112. The smart end points 114 respond by transmitting their present data to the smart utility meter 104.

At 206, the smart utility meter reports the latest totals to the smart utility grid. For purposes of illustration, it is assumed that the smart utility meter 104 reports the most recent energy consumption data to the smart utility grid 102 in response to a request there from. In another illustrative scenario, the smart utility meter 104 is programmed to provide the most recent energy data in accordance with a schedule (e.g., hourly, daily, etc.).

At 208, smart power metering queries the smart end points for the energy consumption totals for the load devices. For purposes of the ongoing illustration, it is assumed that smart power metering 120 within the power supply 116 transmits a query to the smart endpoints 114. Such a query is communicated by way of digital signals superimposed onto the line-level electrical power carried by the branch circuits 110.

At 210, the smart power metering gathers the totals from the smart end points. For purposes of the illustration, it is assumed that the smart power metering 120 receives and stores energy consumption totals transmitted from the smart end points 114 in response to the query at 208 above.

At 212, a user views the energy consumption information on a computer. For purposes of the ongoing illustration, it is assumed that the smart power metering 120 communicates the energy consumption totals to the user notebook computer 118. In turn, the notebook computer 118 uses software, a display or other resources (not shown) to present the energy consumption totals and optionally other information related to the smart utility grid 102 to a user.

### Second Illustrative Method

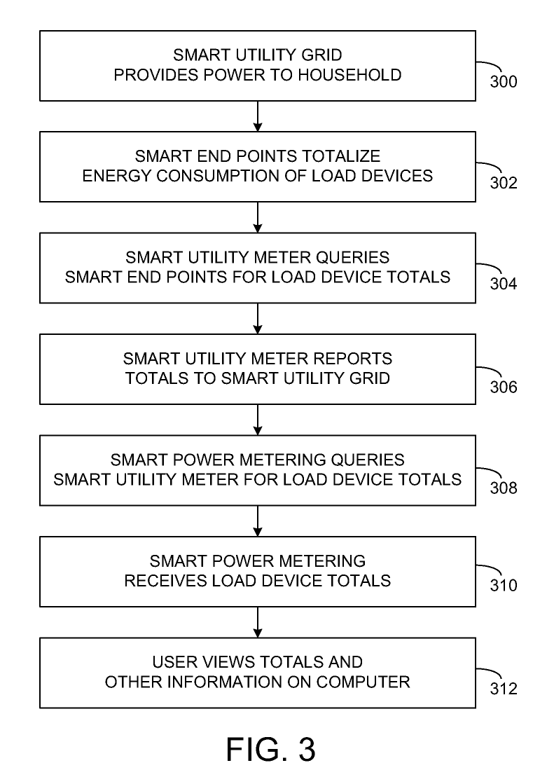

FIG. 3 is a flow diagram depicting a method according to one embodiment of the present teachings. The method of FIG. 3 includes particular operations and order of execution. However, other methods including other operations, omitting one or more of the depicted operations, and/or proceeding in other orders of execution can also be used according to the present teachings. Thus, the method of FIG. 3 is illustrative and non-limiting in nature. Reference is also made to FIG. 1 in the interest of understanding the method of FIG. 3.

At 300, a smart utility grid provides electrical power to a household. For purposes of non-limiting illustration, it is assumed that the smart utility grid 102 provide line-level electrical power to the household 106 by way of the smart utility meter 104 and the panel 108.

At 302, smart end points measure and totalize electrical power consumption of respective load devices. For purpose of the ongoing illustration, it is assumed that the smart end points 114 measure and totalize (i.e., time integrate) electrical power consumption of respective load devices 112. Such totalized information can be stored within the smart end points 114 in terms of Kilowatt hours, volt-ampere hours, etc.

At 304, a smart utility meter queries the smart end points for energy consumption totals for the load devices. For purpose of the ongoing illustration, it is assumed that the smart utility meter 104 queries the smart end points 114 for the most recent energy consumption totals they have accumulated for the respective load devices 112. The smart end points 114 respond by transmitting their present data to the smart utility meter 104.

At 306, the smart utility meter reports the latest totals to the smart utility grid. For purposes of illustration, it is assumed that the smart utility meter 104 reports the most recent energy consumption data to the smart utility grid 102. Such reporting may be performed according to a predetermined schedule, on demand, etc.

At 308, smart power metering queries the smart utility meter for the energy consumption totals for the load devices. For purposes of the ongoing illustration, it is assumed that smart power metering 120 within the smart power supply 116 transmits a query to the smart utility meter 104.

At 310, the smart power metering receives the totals from the smart utility meter. For purposes of the illustration, it is assumed that the smart power metering 120 receives and stores energy consumption totals communicated by the smart utility meter 104.

At 312, a user views the energy consumption information on a computer. For purposes of the ongoing illustration, it is assumed that the smart power metering 120 communicates the energy consumption totals to the user notebook computer 118. In turn, the notebook computer 118 uses software, a display or other resources (not shown) to present the energy consumption totals, and optionally other energy-related information to a user.

The respective methods of FIGS. 2 and 3, as described above, outline just two of numerous ways that smart electrical systems (e.g., 100) can provide energy-related information to a computer user. Additionally, the smart power supply 116 includes smart power metering 120 that enables a user to monitor the electrical consumption of the computer 118 and some of the load devices 112, and to keep apprised of other information regarding the smart utility grid 102. In this way, a user within the household 106 can take steps to conserve power based on time-of-day utility rates, power peaking, grid loading, etc.

Furthermore, some or all of the smart end points 114 can be programmed by way of user input to the computer 118 (by way of appropriate software) so as to automate certain energy conservation strategies. The smart power supply 116 and its respective resources make this possible.

### Second Illustrative System

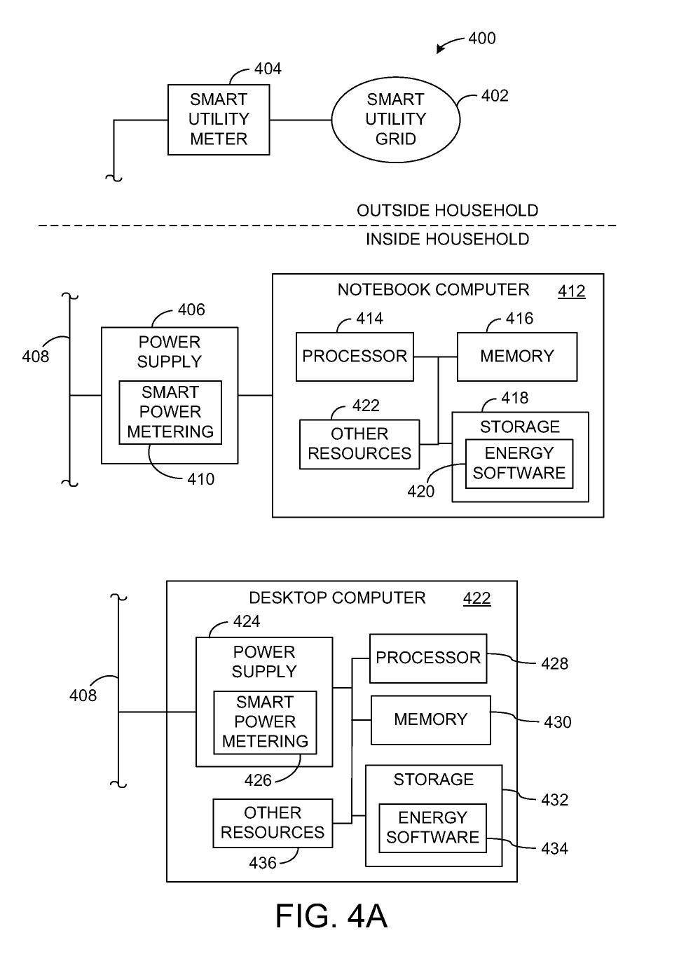

FIG. 4 depicts a diagrammatic view of a system 400. The system 400 is illustrative and non-limiting with respect to the present teachings. Thus, other systems can be configured and/or operated in accordance with the present teachings. The system 400 includes a smart utility grid 402 and a smart utility meter 404 that are configured and cooperative substantially as described above in regard to smart utility grid 102 and smart utility meter 104, respectively.

The system 400 also includes a smart power supply 406. The smart power supply 406 is connected to receive line-level electrical power (e.g., one-hundred twenty volts RMS, etc.) from a branch circuit 408. The branch circuit 408 is electrically coupled to the smart utility grid 402 by way of the smart utility meter 404. The smart power supply 406 is configured to provide normal operating power to a notebook computer 412.

The smart power supply 406 includes smart power metering 410 configured to measure electrical power consumed by the smart power supply 406 and the notebook computer 412. The smart power metering 410 is further configured to communicate data and information, including electrical consumption values, with and between the smart utility meter 404 and the notebook computer 412. In this way, the smart power metering 410 couples the notebook computer 412 in digital communication with the smart utility grid 402.

The notebook computer 412 of the system 400 includes a processor 414 and memory 416, which are respectively defined and configured as is familiar to one of ordinary skill in the computer and related arts. The notebook computer also includes storage 418. The storage 418 is configured to store and retrieve computer-readable code and data accessible to the processor 414. The storage 418 can be defined by any suitable non-volatile storage such as, for non-limiting example, read-only memory (ROM), magnetic media, optical media, programmable read-only memory (PROM), etc. Other suitable forms of storage 418 can also be used. The storage 418 includes energy software 420. The energy software 420 includes program code executable by the processor 414 so that power consumption data and related information received from the smart power supply 406 can be displayed to a user. The energy software 420 can be configured to cause the processor 414 to perform other energy-related tasks as well.

The notebook computer 412 also includes other resources 422 as required or desired. Non-limiting examples of such other resources 422 include an electronic display, a keyboard, a mouse or similar user input device, etc. One having ordinary skill in the computer arts can appreciate that the notebook computer 412 can include any number of various resources (i.e., subsystems and components), and further elaboration is not needed for an understanding of the present teachings.

The smart power supply 406 is located external to the notebook computer 412. Reference is made to FIG. 4B, which depicts a branch circuit 408 (shown as a convenience receptacle), a smart power supply 406 and a notebook computer 412. In this way, the smart power supply 406 can be provided to operate with various notebook computers (e.g., 412), regardless of whether or not each computer is configured to communicate with the smart power supply 406 by way of digital signals. For example, smart power supply 406 can be sold as a replacement for an older power supply and used with an older notebook computer. Thus, a degree of backward compatibility is achieved. Alternatively, the smart power supply 406 can be provided with a new, energy-smart notebook computer so as to fully leverage the energy savings opportunities of a smart utility grid (e.g., 402).

The system 400 further includes desktop computer 422. The desktop computer 422 includes a smart power supply 424 including smart power metering 426. The smart power supply 424 is coupled to receive line-level electrical energy from the branch circuit 408. The desktop computer 422 further includes a processor 428, memory 430, storage 432, energy software 434 and other resources 436, which are defined and configured substantially as described above with respect to elements 414, 416, 418, 420 and 422, respectively.

The smart power supply 424 is located internal to desktop computer 422—that is, within a main housing including the processor 428, the memory 430, etc. The smart power supply 424 can be provided as a part of a new computer or as a replacement power supply for an older computer. The smart power supply 424 operates so that a user can monitor energy consumption of the desktop computer 422 and receive utility rates and other information from the smart utility grid 402, etc. Additionally, the smart power supply 424 is configured to communicate energy consumption data for the desktop computer 422 to the smart utility grid 402.

### First Illustrative Embodiment

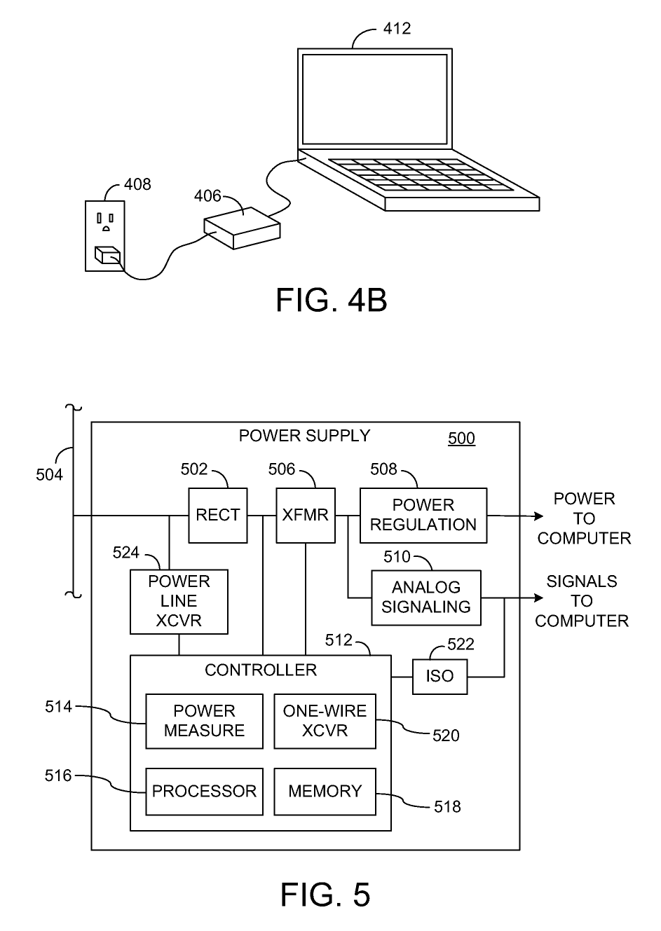

FIG. 5 is a block diagram depicting a smart power supply 500. The smart power supply 500 is illustrative and non-limiting in nature. As such, other smart power supplies are contemplated by the present teachings.

The smart power supply 500 includes a rectifier 502 configured to receive alternating-current (AC) line power from a branch circuit 504 and to provide rectified electrical energy. The smart power supply 500 also includes a transformer 506 configured to receive the rectified electrical energy from the rectifier 502 and to provide pulses of electrical power of reduced voltage. The transformer 506 operates in accordance with control signaling provided by a controller described hereinafter.

The smart power supply 500 also includes power regulation 508 configured to receive the pulses of electrical energy from the transformer 506 and to provide conditioned direct-current (DC) electrical power to a computer (e.g., 412, 422, etc.). The power regulation 508 can be configured to condition one or more electrical characteristics such as voltage regulation or limiting, current limiting, ripple filtering, etc. The specific operations of the power regulation 508 are not germane to the present teachings.

The smart power supply 500 also includes analog signaling 510. The analog signaling 510 is configured to provide DC-level or low-frequency signals to a computer (e.g., 412, etc.) such as throttling signals, maximum rating for the smart power supply 500, etc. Other kinds of analog signaling can also be provided.

The smart power supply 500 also includes a controller 512. The controller 512 is configured to control normal operations of the smart power supply 500 such as, for non-limiting example, operation of the transformer 506 in accordance with power output demands of the computer being served. The controller 512 includes power measuring resources 514 configured to measure the electrical energy consumed by the smart power supply 500 and the computer (i.e., load) that it serves. The power measuring resources 514 are also configured to quantify the electrical energy values as digital data. In one embodiment, the power measuring resources 514 include a power factor correction integrated circuit that includes power measuring capability.

The controller 512 also includes a processor 516. The processor 516 is configured to operate according to a computer-readable program code. The processor 516 is further configured to receive energy consumption data from the power measuring resources 514 and to store those values into a memory 518 of the controller 512.

The controller 512 further includes a one-wire transceiver 520 that is coupled to the analog signaling 510 by way of electrical isolation circuitry 522. The one-wire transceiver 520 is configured to communicate data from the processor 516 to a computer (e.g., 412) by way of superimposing digital signals onto the analog signals provided by analog signaling 510. Additionally, the one-wire transceiver 520 is configured to extract digital signals sent by a computer (e.g., 412) from the analog signaling 510 and to provide corresponding data to the processor 516. In this way, bidirectional data communication is provided between the smart power supply 500 and a computer being served.

The smart power supply 500 further includes a power line transceiver 524. The power line transceiver is configured to superimpose digital signal onto, and to extract digital signals from, line-level electrical energy at the branch circuit 504. In this way, the power line transceiver 524 provides for bidirectional data communications between the processor 516 and various smart entities of a smart utility grid (e.g., 402). For non-limiting example, the power line transceiver 524 provides for data communication between the processor 516 and a smart utility meter 104, various smart end points 114, etc. In turn, a computer (e.g., 412) is also coupled in data communication with elements of a smart utility grid (e.g., 402) by way of the smart power supply 500.

The smart power supply 500 can be defined by various suitable housing, form factor and other characteristics so as be disposed internally or externally with respect to a computer (e.g., 422, 412, etc.) being served. The smart power supply 500 of the present teachings can be provided as new equipment or as a replacement/upgrade. A computer user can take advantage of the energy and cost savings opportunities offered by smart utility grids by way of smart power supplies of the present teachings.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A power supply, comprising:
a controller including a processor;
metering configured to measure electrical power provided from source to the power supply and to provide corresponding power values to the controller;
a first transceiver configured to couple the controller in communication with a computer; and
a second transceiver configured to couple the controller in communication with the source.

2. The power supply according to claim 1 further comprising memory configured to store the power values.

3. The power supply according to claim 1 further comprising throttling circuitry configured to provide control signals to the computer.

4. The power supply according to claim 3, the control signals defined by analog signals, the first transceiver further configured to superimpose digital signals onto the analog signals.

5. The power supply according to claim 1, the first transceiver including a one-wire transceiver.

6. The power supply according to claim 1, the second transceiver further configured to superimpose digital signals onto line-level electrical power.

7. The power supply according to claim 1, the source being defined by a smart utility grid.

8. The power supply according to claim 1, the controller further configured to provide the power values to the computer by way of the first transceiver.

9. The power supply according to claim 1, the controller further configured to provide the power values to the source by way of the second transceiver.

10. The power supply according to claim 1, the controller further configured to:
receive data corresponding to power consumption of one or more load devices coupled to the source by way of the second transceiver; and
provide the data to the computer by way of the first transceiver.

11. A method, comprising:
measuring electrical power provided from a source to a power supply; and
communicating data corresponding to the measuring from the power supply to a computer, the computer being electrically coupled to receive operating power from the power supply.

12. The method according to claim 11, the communicating the data from the power supply to the computer performed by way of superimposing digital signals onto analog signals provided from the power supply to the computer.

13. The method according to claim 11 further comprising communicating the data from the power supply to a smart utility grid by way of superimposing digital signals onto line-level electrical power.

14. The method according to claim 11 further comprising:
providing a power measurement to the power supply, the power measurement corresponding to a load device coupled to the source; and
communicating the power measurement from the power supply to the computer.

15. The method according to claim 14, the providing the power measurement to the power supply performed by way of superimposing digital signals onto line-level electrical power.
